(19) United States
(12) Patent Application Publication
(10) Pub. No.: US 2025/0140538 A1
(43) Pub. Date: May 1, 2025

(54) MODEL-DRIVEN PRESSURE ESTIMATION

(71) Applicant: Applied Materials, Inc., Santa Clara, CA (US)

(72) Inventors: Devi Raghavee Veerappan, Eindhoven (NL); Ajit Balakrishna, Santa Clara, CA (US)

(21) Appl. No.: 18/495,458

(22) Filed: Oct. 26, 2023

(51) Int. Cl. H01J 37/32; G06F 30/27

(52) U.S. Cl. CPC H01J 37/32926; G06F 30/27; H01J 37/32816; H01J 2237/24585

(57) ABSTRACT

A method for estimating pressure values within a processing chamber is provided. The method can include receiving a measurement of a pressure at a terminal end of an exit flow path from a processing chamber, and processing the measurement of the pressure using a model including conductance values for a plurality of segments of the exit flow path to estimate one or more pressure values within the processing chamber.

### TECHNICAL FIELD

Embodiments of the present disclosure relate generally to generating model-driven pressure estimates.

### BACKGROUND

Understanding and controlling the pressure within a substrate processing chamber is a useful aspect of substrate manufacturing. The pressure within the chamber can greatly impact characteristics of the substrate being produced. For example, in substrate processes such as Atomic Layer Deposition (ALD), Chemical Vapor Deposition (CVD), etc. precise pressure control ensures uniform layer deposition. Similarly, in etching processes, the pressure in the chamber affects the rate at which material is removed from the substrate, finely impacting a finished product's dimensions and tolerances. Incorrect pressure levels can lead to defects, including impurities or structural inconsistencies.

Pressure levels are monitored and controlled through a range of sensors, control systems, and pressure sources (e.g., vacuum sources or vents).

The configuration of these components with respect to the chamber can vary; for example, a vacuum source may be located close to the chamber or at a considerable distance. To regulate a vacuum pump effectively, a sensor is often employed. The sensor is generally placed at or near the vacuum pump. A pressure measured away from a processed substrate may vary from the pressure at the substrate. Accordingly, it can be difficult for engineers to accurately determine the pressure at a substrate during processing.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one aspect of the present disclosure, a method is provided. The method includes receiving a measurement of a first pressure value at a terminal end of an exit flow path from a processing chamber; and processing the measurement of the first pressure value using a model comprising conductance values for a plurality of segments of the exit flow path to estimate one or more pressure values within the processing chamber.

In another aspect of the present disclosure, a system is provided. The system includes a memory device; and a processing device communicatively coupled to the memory device. In some aspects, the processing device is to receive a measurement of a first pressure value at a terminal end of an exit flow path from a processing chamber; and process the measurement of the first pressure value using a model comprising conductance values for a plurality of segments of the exit flow path to estimate one or more pressure values within the processing chamber.

In another aspect of the present disclosure, a non-transitory computer readable storage medium is provided. The non-transitory computer readable storage medium includes instructions that, when executed by a processing device, causes the processing device to perform operations including receiving a measurement of a first pressure value at a terminal end of an exit flow path from a processing chamber; and processing the measurement of the first pressure value using a model comprising conductance values for a plurality of segments of the exit flow path to estimate one or more pressure values within the processing chamber.

### BRIEF DESCRIPTION OF THE DRAWINGS

Aspects and implementations of the present disclosure will be understood more fully from the detailed description given below and from the accompanying drawings, which are intended to illustrate aspects and implementations by way of example and not limitation.

FIG. 1A illustrates an example system architecture capable of supporting a prediction engine that generates model-driven pressure estimates, according to some embodiments of the present disclosure.

FIG. 1B illustrates an example processing chamber of FIG. 1A, according to some embodiments of the present disclosure.

FIG. 2A illustrates an example model-driven estimation process as performed by the prediction engine of FIG. 1A, according to some embodiments of the present disclosure.

FIG. 2B illustrates an example flow structure, according to some embodiments of the present disclosure.

FIG. 3A illustrates an example flow structure of a manufacturing system, according to some embodiments of the present disclosure.

FIG. 3B illustrates an exemplary rectangular duct segment of the flow structure of FIG. 3A, according to some embodiments of the present disclosure.

FIG. 3C illustrates an exemplary annular flow segment of the flow structure of FIG. 3A, according to some embodiments of the present disclosure.

FIG. 4 illustrates an exemplary plasma screen of the flow structure of FIG. 3A, according to some embodiments of the present disclosure.

FIG. 5A illustrates a side-view of an example portion of a processing chamber as seen in FIG. 3A, according to some embodiments of the present disclosure.

FIG. 5B illustrates a top-down view of an example portion of a processing chamber as seen in FIG. 3A, according to some embodiments of the present disclosure.

FIG. 6 illustrates a top-down view of example zones of the processing chamber of FIG. 3A, according to some embodiments of the present disclosure.

FIG. 7 illustrates a flow chart of an example method for estimating pressure values within a processing chamber, according to some embodiments of the present disclosure.

FIG. 8 illustrates an embodiment of a diagrammatic representation of a computing device associated with a substrate manufacturing system, in according to some embodiments of the present disclosure.

### DETAILED DESCRIPTION

In order to accurately determine pressure values at one or more locations on a substrate during processing of the substrate, it would be useful to have a pressure sensor as close as possible to a substrate. Additionally, it would be useful to have a vacuum source as close as possible to the process chamber used to process the substrate. However, due to practical considerations within large scale industrial settings, this may not be feasible. A common challenge within substrate manufacturing systems is designing a system layout that facilitates fine pressure control and sensing.

For example, in some cases, the distance between the vacuum source and the process chamber can be such that it affects the uniformity of the pressure within the chamber. The inclusion of filters, passageways, multiple chambers, etc. can introduce non-uniform pressure levels within a given processing chamber. Large non-uniformities in chamber pressure levels can reduce the control on overall pressure, leading to inconsistencies and degradation in substrate processing quality.

In some cases, placing a pressure sensor to mitigate the above challenges can be difficult. It may not always be feasible to place a pressure sensor close to the substrate due to spatial constraints or other technical limitations. Instead, the pressure sensor might be located away from the substrate and/or outside of the process chamber, such as near a pump or in a position that is otherwise not close to the substrate. This can result in pressure sensor readings that do not accurately reflect the pressure conditions at the substrate's location.

These manufacturing and system constraints can lower finished substrate quality, cause increased system and part maintenance, and overall, unnecessarily increase consumption of resources.

Thus, embodiments described herein address the above, and other challenges, by introducing virtual pressure sensor (e.g., a prediction engine) that can generate model-driven predictions for the flow parameters and associated pressures as gas is flowing through a flow structure. The prediction engine can generate and deploy an analytical model that can estimate pressure and flow at specific locations of the flow structure. This may include estimates at various locations or regions along the substrate surface. Embodiments enable precise pressure mappings at a surface of a processed substrate and/or at other locations in a process chamber or in a flow structure associated with the process chamber. Such precise pressure mappings may have many benefits, and may be usable to determine process parameters for a process performed on a substrate, such as temperature, flow rates, pressure settings, and so on. In some case process parameters may be adjusted to optimize a process in response to the estimated pressure values at one or more locations in a process chamber (e.g., at one or more locations on a processed substrate).

In embodiments, the analytical model may take into account various factors, such as chamber geometry, flow dynamics, process temperatures, etc. to provide accurate estimates of the pressure conditions directly where processes are occurring i.e., the substrate surface. In embodiments, the analytical model is or includes a network conductance model. In embodiments, the analytical model may estimate pressures at one or more locations within a process chamber (e.g., at one or more regions of a substrate under process) in real time or near-real time during processing. In embodiments, the analytical model may estimate pressures at one or more locations within a process chamber in less than 2 seconds, in less than 1 second, in less than 0.5 seconds, or quicker. Accordingly, the model may have a quick run time. For example, due to its analytical nature, the model may provide estimates and predictions in real-time as gas flow is in motion.

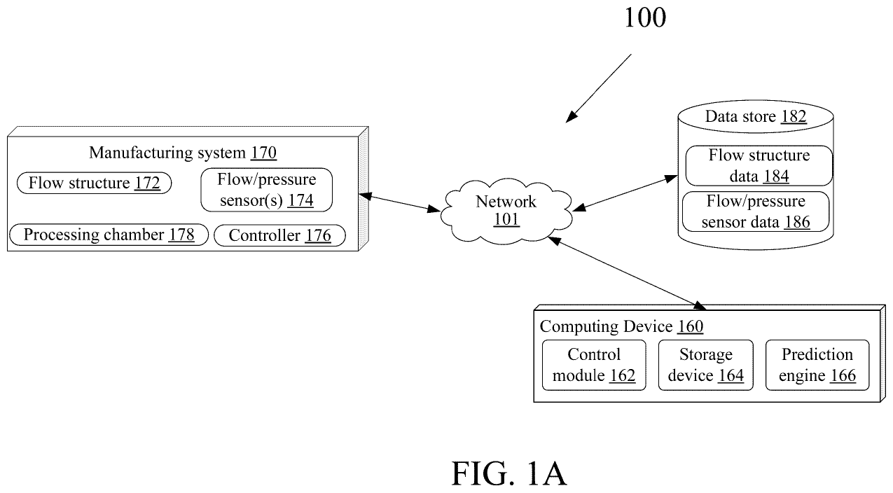

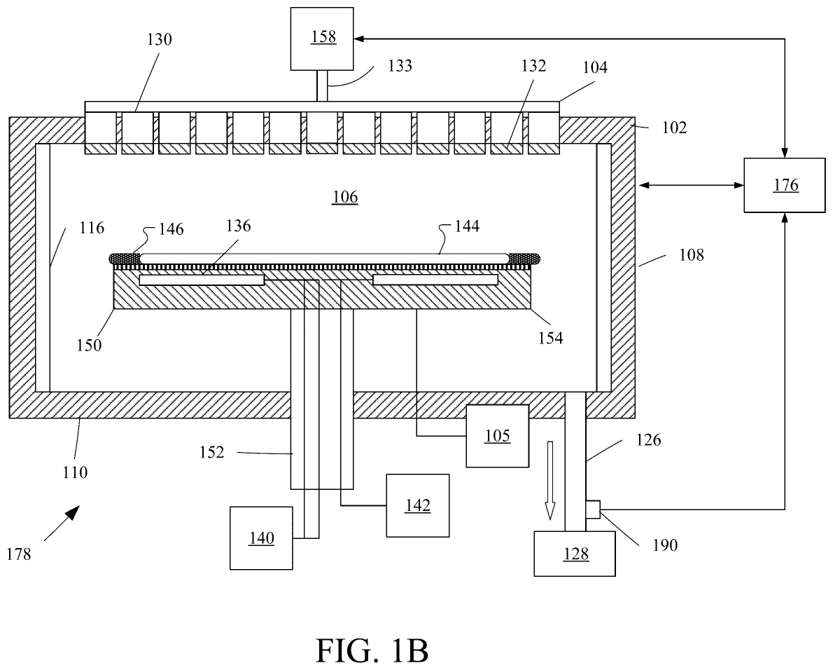

FIG. 1A illustrates an example system architecture 100 capable of supporting a prediction engine 166 that generates model-driven pressure estimates, according to some embodiments of the present disclosure.

The system architecture 100 (also referred to as “system” herein) includes a computing device 160 connected to a data store 182 and a manufacturing system 170 via a network 101. Data store 182 may be or include, for example, a database, network storage, and so on. In embodiments, data store 182 stores flow structure data 184 and/or flow and/or pressure sensor data.

In some embodiments, manufacturing system 170 can include a gas flow structure 172, and one or more flow sensors and/or pressure sensors 174, for sensing flow parameters and/or pressure parameters within the manufacturing flow structure. Manufacturing system 170 can also include a processing chamber 178 and a controller 176 for controlling and monitoring a variety of processing parameters of a process performed on substrates in the processing chamber 178. Flow structure 172, flow sensors and/or pressure sensors 174, and controller 176 can be organized or combined in several configurations. For example, in some embodiments, flow sensors and/or pressure sensors 174 may be included in flow structure 172, and/or in processing chamber 178. A flow structure such as flow structure 172 may include each portion of a flow path between a processing chamber and a vacuum pump in embodiments, and may include the processing chamber 178. For example, a flow structure may include a geometry of the processing chamber, one or more portions of an exhaust conduit from the processing chamber, and so on.

In some embodiments (as shown), the prediction engine 166 runs on a computing device (e.g., a server machine) 160 that is remote from processing chamber 178. Computing device 160 may collocated with manufacturing system 170 (e.g., may be located at a fabrication facility that includes manufacturing system 170), in which case network 101 may be or include a local area network (LAN). Alternatively, computing device 160 may not be collocated with manufacturing system 170 (e.g., may be in a different geographic location from manufacturing system 170), in which case network 101 may include a LAN, a wide area network (WAN), the Internet, or a combination thereof.

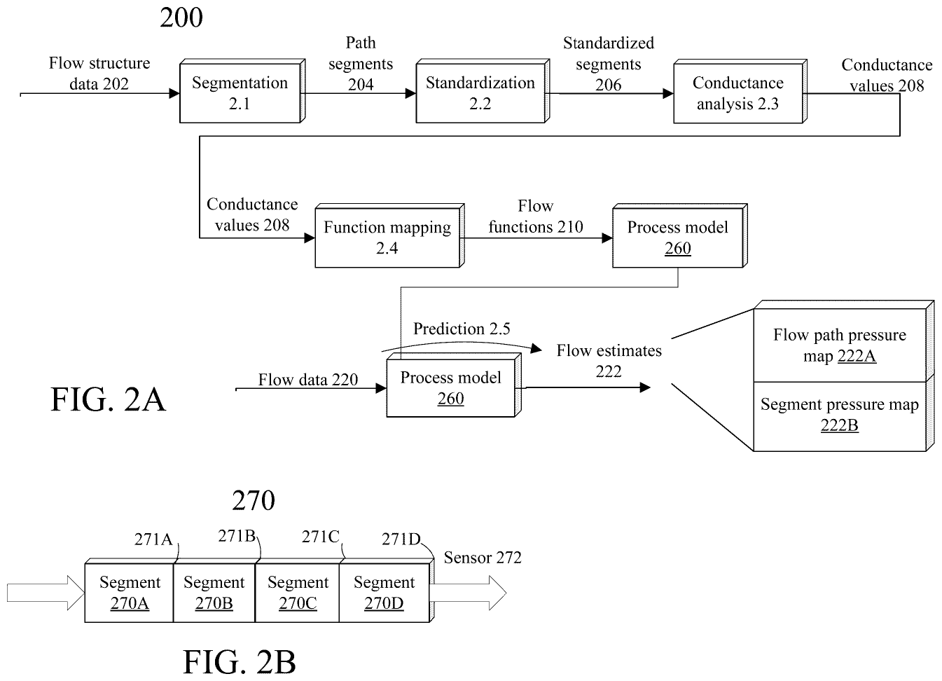

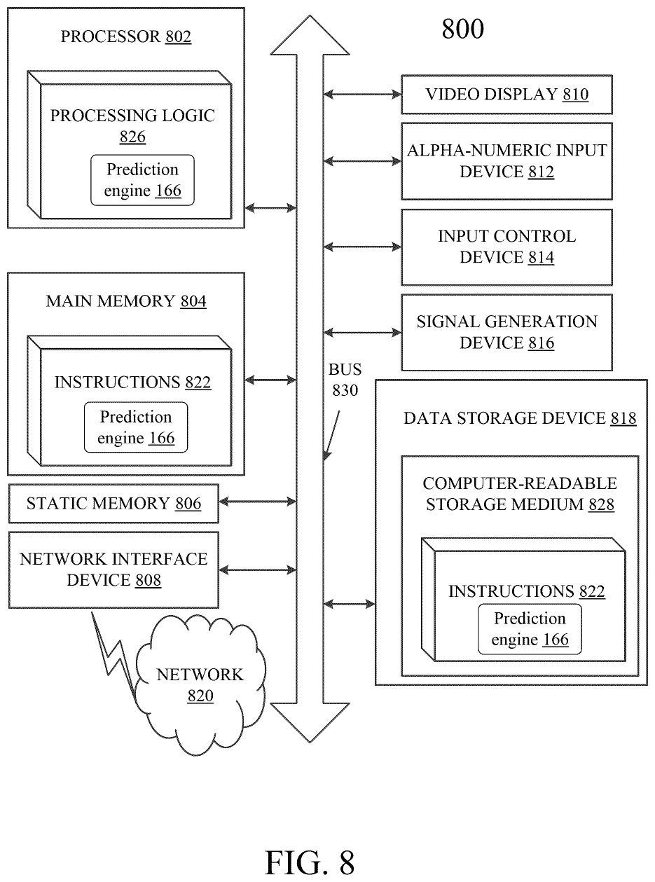

In embodiments, computing device 160 may include a control module 162, one or more local storage device 164 and/or prediction engine 166. In embodiments, computing device may correspond to computing device 800 of FIG. 8). In embodiments, execution of the instructions by computing device 160 causes computing device 160 to perform the method of FIGS. 2A-B.

In some embodiments, computing device 160 is a component of manufacturing system 170. For example, computing device 160 may be directly connected to manufacturing system 170 rather than being connected via network 101. In some embodiments, prediction engine 166 runs on controller 176.

In some cases, computing device 160 can engage with data store 182 and manufacturing system 170. Computing device 160 can include a prediction engine 166, a control module 162, and a storage device 164. In some cases, the prediction engine 166 may generate model-driven estimates of flow parameters from limited flow data by generating an analytical process model, and then using the analytical process model to predict flow parameters based on limited flow data.

For example, in some cases, a manufacturing system may include piping, a chamber, and any number of sections. Prediction engine 166 may generate or include a digital model of the system. Once the model has been generated, the prediction engine 166 can estimate flow and/or pressure parameters such as pressure and/or flow rate of a gas through different points of the flow structure. Furthermore, these estimations can be based on one or a few measurements. Thus, the model-driven prediction capabilities of the prediction engine 166 can be a powerful tool for assessing and estimating the conditions in chambers and structures that would traditionally be difficult to reach, or access. Such a process will be further described with respect to FIG. 2A.

In some embodiments, flow data and/or pressure data used may correspond to flow structure data 184 and/or flow sensor data 186 in data store 182. In some cases, flow data and/or pressure data used may be associated with flow structure 172 and flow sensors and/or pressure sensors 174.

In some embodiments, server machine 160, data store 182, and manufacturing system 170 may all be connected via a network 101. In certain embodiments, the network may include a public network (e.g., the Internet), a private network (e.g., a local area network (LAN) or wide area network (WAN)), a wired network (e.g., Ethernet network), a wireless network (e.g., an 802.11 network or a Wi-Fi network), a cellular network (e.g., a Long Term Evolution (LTE) network), routers, hubs, switches, server computers, and/or a combination thereof.

In other embodiments, server machine 160 and data store 182 may all be a part of one computing device or one server, and transmit data internally (e.g., over a suitable bus/interconnect) and without the use of a network. The computing device may include cloud-based computers, data processing servers, personal computers (PCs), laptops, mobile phones, smart phones, tablet computers, netbook computers, network-connected televisions, rack mount servers, etc.

In some embodiments, flow structure data and flow data for processing by the prediction engine 166 may be stored and returned to data store 182. For example, flow structure data 184 can be transferred to prediction engine 166 to generate a process model. After, flow sensor data and/or pressure data 186 from data store 182 can be fed to the process model. Flow parameter predictions and/or pressure parameter predictions can be returned to the data store. In other embodiments, the flow parameter predictions and/or pressure parameter predictions can be transferred to the manufacturing system 170.

For example, in some cases, the flow structure data 184 and flow sensor data and/or pressure data 186 may correspond to the flow structure 172, and the sensor data 186 may have been gathered by flow sensors and/or pressure sensors 174. In such cases, the flow parameter estimates and/or pressure parameter estimates can be passed on to controller 176, which may adjust other process parameters within the manufacturing equipment in response to the predicted parameters. In some embodiments, control module 162 may perform intersystem communications.

In some embodiments, any of data store 182 and/or storage device 164 is a persistent storage that is capable of storing data as well as data structures to tag, organize, and index the data. A data item may include time-series data of flow rate or pressure. A data item may further include structural, or dimensional data, associated with a flow structure of the manufacturing system, in accordance with embodiments described herein. Data store 182 and/or storage device 164 may be hosted by one or more storage devices, such as main memory, magnetic or optical storage-based disks, tapes or hard drives, network-attached storage (NAS), storage area network (SAN), and so forth. In some embodiments, data store 182 and/or storage device 164 may be a network-attached file server, while in other embodiments, data store(s) data store 182 and/or storage device 164 may be some other type of persistent storage such as an object-oriented database, a relational database, and so forth, that may be hosted on one or more different machines coupled the system architecture 100 via a network. In some embodiments, the data store(s) 182 and/or storage device 164 may store portions of flow structure or flow data.

In some embodiments, any one of the associated modules or servers, including system 170, may temporarily accumulate and store data until it is transferred to data store 182 for permanent storage.

Referring to FIG. 1B, processing chamber 178 may perform plasma-based processes in embodiments. Alternatively, processing chamber may perform non-plasma processes. The processing chamber 178 may be coupled to a plasma source 158 via one or more gas delivery lines 133. The processing chamber 178 may be, for example, a plasma etch reactor, a deposition chamber, an ashing chamber, etc. The processing chamber may be suitable for an etching operation, a deposition operation, a chamber cleaning operation, a plasma treatment operation, or any other type of operation typical of a semiconductor manufacturing facility. In an embodiment, one or more substrates (e.g., wafers) 144 may be provided within the processing chamber 178. In an embodiment, the processing chamber 178 may be maintained at a pressure suitable for the target operation. In a particular embodiment, the pressure may be between approximately 1 Torr and approximately 200 Torr.

The processing chamber 178 and/or plasma source 158 may be connected to a controller 176, which may control processing of the plasma source 158 and/or processing chamber 178 (e.g., by controlling set points, loading recipes, and so on). One or more flow sensors and/or pressure sensors may be connected to the gas delivery line(s) to detect gas flow characteristics in some embodiments.

In embodiments, the plasma source 158 is a remote plasma source (RPS) that generates plasma at a remote location and delivers the externally generated plasma to the processing chamber. Alternatively, the processing chamber may include an integrated plasma source (not shown) that can generate plasma within the processing chamber.

Processing chamber 178 includes a substrate support assembly 150, according to some embodiments. Substrate support assembly 150 includes a puck 154 (e.g., may include an electrostatic chuck (ESC)). The puck 154 may perform chucking operations, e.g., vacuum chucking, electrostatic chucking, etc. Substrate support assembly 150 may further include base plate, cooling plate and/or insulator plate (not shown).

In embodiments, processing chamber 178 includes chamber body 102 and lid 104 that encloses an interior volume 106. Chamber body 102 may be fabricated from aluminum, stainless steel, or other suitable material. Chamber body 102 generally includes sidewalls 108 and a bottom 110. An outer liner 116 may be disposed adjacent to sidewalls 108, e.g., to protect chamber body 102. Outer liner 116 may be fabricated and/or coated with a plasma or halogen-containing gas resistant material. Outer liner 116 may be fabricated from or coated with aluminum oxide. Outer liner 116 may be fabricated from or coated with yttria, yttrium alloy, oxides thereof, etc.

An exhaust port may be defined in chamber body 102, and may couple interior volume 106 to an exhaust line 126 that in turn couples to a pump system 128. Pump system 128 may include one or more pumps, valves, lines, manifolds, tanks, etc., utilized to evacuate and regulate the pressure of interior volume 106. In embodiments, a pressure sensor and/or flow sensor 190 is disposed in or on the exhaust line. The pressure sensor and/or flow sensor 190 may be used to measure a pressure and/or a gas flow rate at or near pump system 128. Additionally, or alternatively, one or more other pressure sensors and/or flow sensors may be disposed at other locations at the exhaust line 126, in the processing chamber 178 and/or at gas delivery line(s) 133.

Lid 104 may be supported on sidewall 108 of chamber body 102. Lid 104 may be openable, allowing access to interior volume 106. Lid 104 may provide a seal for processing chamber 178 when closed. Plasma source 158 may be coupled to processing chamber 178 to provide process, cleaning, backing, flushing, etc., gases and/or plasmas to interior volume 106 through gas distribution assembly 130. Gas distribution assembly 130 may be integrated with lid 104 in embodiments.

Examples of processing gases that may be used in processing chamber 178 include halogen-containing gases, such as C2F6, SF6, SiC14, HBr, NF3, CF4, CHF3, CH2F3, Cl2 and SiF4. Other reactive gases may include O2 or N2O. Non-reactive gases may be used for flushing or as carrier gases, such as N2, He, Ar, etc. Gas distribution assembly 130 (e.g., showerhead) may include multiple inlets 132 on the downstream surface of gas distribution assembly 130. Inlets 132 may direct gas flow to the surface of substrate 144. In some embodiments, gas distribution assembly may include a nozzle (not pictured) extended through a hold in lid 104. A seal may be made between the nozzle and lid 104. Gas distribution assembly 130 may be fabricated and/or coated by a ceramic material, such as silicon carbide, yttrium oxide, etc., to provide resistance to processing conditions of processing chamber 178.

Substrate support assembly 150 is disposed in interior volume 106 of processing chamber 178 below gas distribution assembly 130. Substrate support assembly 150 may hold a substrate 144 during processing. An inner liner (not shown) may be coated on the periphery of substrate support assembly. The inner liner may share features (e.g., materials of manufacture, function, etc.) with outer liner 116.

Substrate support assembly 150 may include supporting pedestal 152, insulator plate, base plate, cooling plate, and puck 154. Puck 154 may include electrodes 136 for providing one or more functions. Electrodes 136 may include chucking electrodes (e.g., for securing substrate 144 to an upper surface of puck 154), heating electrodes, RF electrodes for plasma control, etc.

Protective ring 146 may be disposed over a portion of puck 154 at an outer perimeter of puck 154. Puck 154 may be coated with a protective layer (not shown).

Puck 154 may further include multiple gas passages such as grooves, mesas, and other features that may be formed in an upper surface of puck 154. Gas passages may be fluidly coupled to a gas source 105. Gas from gas source 105 may be utilized as a heat transfer or backside gas, may be utilized for control of one or more lift pins of puck 154, etc. Multiple gas sources may be utilized (not shown). Gas passages may provide a gas flow path for a backside gas such as He via holes drilled in puck 154. Backside gas may be provided at a controlled pressure into gas passages to enhance heat transfer between puck 154 and substrate 144.

Puck 154 may include one or more clamping electrodes. The clamping electrodes may be controlled by chucking power source 140. Clamping electrodes may further couple to one or more RF power sources through a matching circuit for maintaining a plasma formed from process and/or other gases within processing chamber 178. The RF power sources may be capable of producing an RF signal having a frequency from about 50 kilohertz (kHz) to about 3 gigahertz (GHz) and a power of up to about 10,000 Watts. Heating electrodes of puck 154 may be coupled to heater power source 142.

Controller 176 may control one or more parameters and/or set points of the plasma source 158 and/or processing chamber 178. System controller 176 can be and/or include a computing device such as a personal computer, a server computer, a programmable logic controller (PLC), a microcontroller, and so on. System controller 176 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. System controller 176 can include a data storage device (e.g., one or more disk drives and/or solid-state drives), a main memory, a static memory, a network interface, and/or other components.

System controller 176 can execute instructions to perform any one or more of the methodologies and/or embodiments described herein. The instructions can be stored on a computer readable storage medium, which can include the main memory, static memory, secondary storage and/or processing device (during execution of the instructions). In embodiments, execution of the instructions by system controller 176 causes system controller to perform the methods of FIG. 2A.

In embodiments, system controller 176 may receive measurements from one or more flow sensors and/or pressure sensors indicating a flow parameter and/or pressure parameter (e.g., pressure, flow rate, etc.). A prediction engine 166 (e.g., which may execute on controller 176) may process the received pressure measurement(s) and/or flow measurement(s), and may estimate pressure values and/or flow values at one or more locations in the processing chamber 178 (e.g., at one or more regions on a processed substrate 144). Controller 176 may adjust one or more properties or settings (e.g., such as a plasma power, temperature, plasma frequency, pump rate, gas flow rate for one or more gases, etc.) of plasma source 158 and/or processing chamber 178 responsive to the measured radical concentration. System controller 176 can also be configured to permit entry and display of data, operating commands, and the like by a human operator.

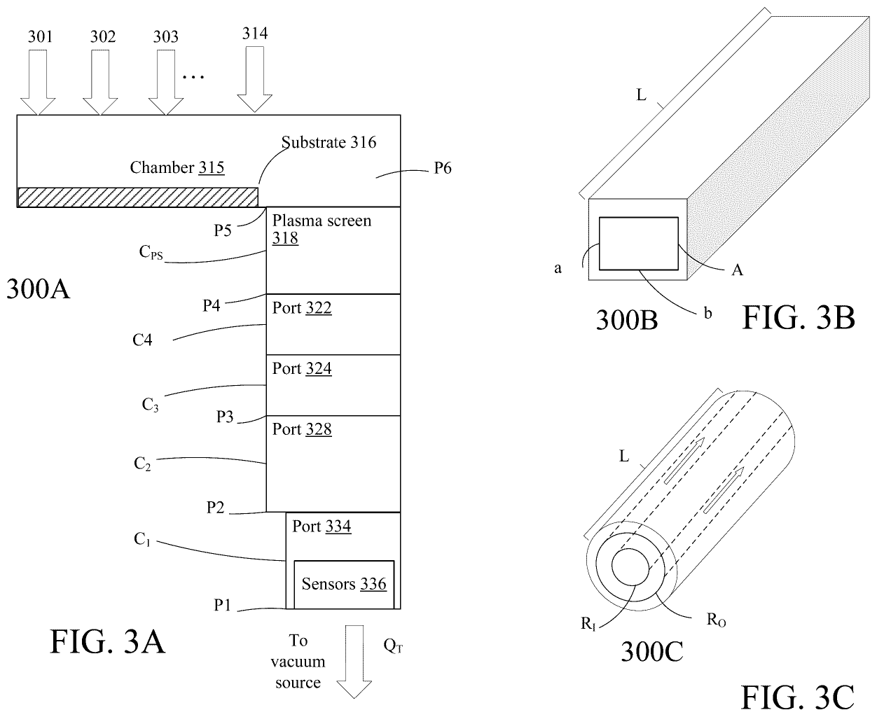

In embodiments, data captured from sensors such as sensors 174 of FIG. 1A and/or pressure sensor and/or flow sensor 190 and/or structural data associated with processing chamber 178 can be stored in data store 182 of FIG. 1A. In embodiments, data store 182 can include flow structure data 184 and flow sensor data 186. In some embodiments, flow structure data 184 can be physical, or geometric, structural data of a structure in which fluid, (e.g., gas) is flowing through. Such structures and geometries will be further discussed with respect to FIGS. 3-6. In some embodiments, flow sensor data and/or pressure sensor data can include a single dataset, which includes the parameters for a gas flow through an associated flow structure as a function of time. In some embodiments, the data within data store 182 can be associated with real gas flow through manufacturing system 170. In other cases, the data in data store 182 may be different, and manufacturing system 170 may produce and store its respective associated data externally.

FIG. 2A illustrates an example model-driven estimation process 200 as performed by the prediction engine 166 of FIG. 1A, according to some embodiments of the present disclosure.

In some embodiments, the model-driven prediction process 200 may be intimately tied with a physical flow structure. As seen in FIG. 2B, the process 250 may be tied to example flow structure 270.

FIG. 2B illustrates an example flow structure 270, according to some embodiments of the present disclosure. Example flow structure 270 may include segments 270A, 270B, 270C, 270D, and a single pressure sensor 272. Alternatively, more or fewer flow segments may be included, and/or more sensors 272 may be included. In some embodiments, flow structure 270 may be a part of exhaust vacuum system that exhausts gas from segment 270A, through segment 270B-C, and out through segment 270D. Exhausting gases through the segments may lower the pressure within one or more of the segments, and may cause a vacuum at flow structure 270 (e.g., which may correspond to a processing chamber).

Although example flow structure 270 is represented in FIG. 2B as a series of cubes, or rectangular ducts, the illustration is exemplary. One can imagine each segment 270A-D of example flow structure 270 as including chambers, rectangles, cubes, filters, spheres, complex shapes, and/or any other structures and/or geometries that may be included in a gas flow structure.

To begin process 200, the flow structure 202 under observation is to be first dissected into simpler, more manageable geometric segments at segmentation operation 2.1. Segmentation operation 2.1 can be executed by a computer module, or a human counterpart, and may be executed with the objective of segmenting a complex flow structure into elementary shapes, such as cubes, cylinders, or spheres, when possible. Analytical flow equations may be determined for each of these basic shapes. Additionally, analytical flow equations may also be computed for more complex shapes, for filters, and so on.

In the example of example flow structure 270, for simplicities sake, each segment 270A-D may be a rectangular (or cubic) duct. Segmentation at operation 2.1 would divide the total example flow structure 270 into those four equal rectangular structures, for which equations may be determined. Should a portion be irregular, such as amorphous, or bent, etc., the irregular portion may be considered a separate segment, with the segmentation operation 2.1 being used to divide out natural and intuitive segments from within the flow structure path.

Thus, segmentation operation 2.1 may result in a series of three-dimensional flow conduits, or path segments 204. One or more path segments 204 may be selected to emulate one of the elementary geometric shapes as closely as possible. Alternatively, or additionally, some path segments 204 may have more complex shapes. The boundaries and interfaces between these path segments 204 may be clearly marked, serving as the zones where flow parameters may later be coupled.

To formalize this segmentation in a computer module, a schematic representation or computational mesh may be generated. Such a mesh may serve as a spatial map that outlines the segmented regions (e.g., path segments 204), providing a structured framework for the subsequent application of analytical flow equations. The mesh may be constructed to be sufficiently fine-grained, ensuring that the segmented approximation closely mirrors the actual flow structure.

After the path segments 204 (e.g., which may correspond to segments 270A-D in an example) have been selected, each segment can be standardized, and the corresponding dimensions extracted. For example, if path segments 270A-D have been segmented, standardization operation 2.2 may iterate through each path segment to identify which elementary flow structure might most closely approximate the shape of that path segment.

For example, a segment that is cylindrical with a diminishing diameter could be identified as a funnel. A circular chamber that extends linearly could be identified as a pipe with a specific diameter and length. Furthermore one or more segments could be computationally mapped, and an assimilation score for how closely the segment maps to a standardized shape, such as a cube, or a cylinder, could be generated. Such a standardized score may aid in delivering a confidence score for the output of the model.

Standardization operation 2.2 may further assign labels, transfer points, etc. for one or more segments. In some embodiments, spaces between segments may also be identified. For the example flow structure 270, transfer points 271A-C can be identified. These transfer points 271A-C can serve as input boundary points or positions where boundary conditions between adjoining flow structures are shared. These identified points may be helpful when applying a conductance analysis in conductance analysis operation 2.3. One of ordinary skill in the art, having the benefit of this disclosure, will appreciate that numerous shapes, geometries, and corresponding analytical equations for segments 204 and/or 206 exist, and that rectangular ducts, or funnels, etc. as provided are example representations of segments associated with the system.

Conductance analysis operation 2.3 involves the application of known or determined analytical flow equations to one or more segmented regions of the flow structure. These equations may be selected based on the geometric shapes that respective segments closely mimic, such as a cube, cylinder, or sphere. These equations may generally be derived from fundamental principles of fluid dynamics including the Navier-Stokes equations and empirical equations based on previously done experiments available in literature. These equations may be based on the conservation of fluid mass and moment, but may be simplified so as to increase computational speed and simplicity. These equations may further be modified or simplified to suit the specific geometric shape of the segment.

The equations for a standardized segment may include various flow parameters, including but not limited to fluid parameters including, velocity, pressure, temperature, viscosity, etc. The equations may include various segment dimensions such as cross-sectional area, length, and changes, or variations from the standardized figures. As mentioned, these equations will be described in further detail, for specific shapes and structures, throughout FIGS. 3-5.

In one example, segment 270A of example flow structure 270 is a segment that is cylindrical in shape, and the corresponding flow equations for cylindrical flow would be applied to that particular segment to arrive at a conductance value “C” for that flow segment. As will be further discussed with respect to FIGS. 3-5, the conductance value may be a function of the cylindrical cross-sectional area, length, diameter, fluid viscosity, flow rate, pressure, surface smoothness, and/or other underlying factors of the segment. The flow equations, as will be further seen in FIGS. 3-5, may be modified and/or aggregated to maintain applicability for irregular shapes. The flow equations will also be further discussed according to the dimension and variables they represent. Presently, it is relevant to recognize that conductance analysis operation 2.3 may iterate through one or more standardized segment 206, and assign a specific value for the conductance of each assessed standardized segment. For example flow structure 270, this can indicate that four standardized segments 270A-D will be each assigned a respective conductance value C1-C4.

Different conductance values may vary greatly, depending on the specific functions and dimensions of each particular segment. For example a straight or enlarged section at the outlet of the structure may have a conductance value that varies widely from a segment that is a filter, or a funneling shape, etc. Thus, in some embodiments one or more conductance value may be calculated independently.

From the conductance values 208, at function mapping operation 2.4 a set of appropriate flow functions 210 can be selected to describe how each standardize segment will transform or affect a starting boundary condition, and arrive at an opposite boundary condition between each segment. For example, each standardized segment may correspond to a flow function that describes the flow through that standardized segment. Generally, the flow functions may include parameters that are estimated or measured for a segment. These parameters are each impactful, and may include intake, output, initial and final boundary conditions, and so on. For example, in a cylindrical segment, the parameters might include the radius of the cylinder at an intake, conductance, a velocity of the gas at the inlet or intake, and output the velocity of the gas at an outlet, the pressure drop across the length of the cylinder, and so on.

It is relevant to note that the chosen equations and parameters may describe the flow characteristics within each individual segment and may also be compatible with the equations and parameters of adjacent segments. This ensures that the model can later be coupled effectively across different segments to provide a comprehensive description of the entire flow structure.

In an example, with respect to segment 270D, the boundary conditions at an exiting point, or area, of the segment 271D can be known due to the placement of a sensor 272. These boundary conditions can include attributes such as the fluid flow, pressure at the boundary location, fluid characteristics (e.g., gas density and viscosity, etc.), and so on. A flow function as determined at function mapping operation 2.4, including conductance and standardized segment characteristics, may then be applied to each segment, optionally starting with segment 270C, proceeding to segment 270B, then segment 270A. In such a way, each boundary condition, and the associated parameters through each boundary point 271A-C may be determined from an initial boundary point from which conditions are known in a following prediction operation 2.5.

In an example, the flow equation for segment 270D may intake the boundary condition values from a known boundary (e.g., either end of the segment), and apply the flow function for the segment 270D. This flow function may deliver the conditions at boundary 271C. Once the boundary conditions at the opposite boundary (e.g., boundary 271C) are computed, the flow equation from the adjacent segment 270C can be applied, to prorogate the mapping to the next boundary, and so on and so forth. In such a way, a series of flow functions corresponding to a series of segments can serve to map, estimate or predict, properties of the fluid flow at the boundaries of each segment. These properties, or boundary conditions, can include pressure, flow rate, and/or other fluid characteristics indicative of conditions at a point in time, and based on an initial measurement. In such a way, function mapping operation 2.4 can deliver a set of flow functions, that together can define a process model 260, or a way to estimate flow parameters at a variety of points along the flow structure.

The equations for one or more segments may be solved at prediction operation 2.5 to obtain flow estimates 222 of the flow parameters and/or pressure parameters through the flow structure. These can include a flow path pressure map 222A, as well as more precise pressure values 222B for specific locations or portions within each flow path segment. In embodiments, the flow estimates 222 may include pressure values, flow rate values, mass flow values or any other quantifying values or characteristics for fluid flow within a flow structure.

In embodiments, the flow estimates 222 may correspond to a flow path including a processing chamber and an exhaust path from the processing chamber (as will be further discussed with respect to FIGS. 3A-6). In embodiments, flow path pressure map 222A may correspond to pressure values along an exhaust, or exit path, characterized by path segments 204. In embodiments, segment pressure map 222B may include values or characteristics within each segment. E.g., segment pressure map 222B may correspond to further segmentation or segments of a processing chamber, or any of path segments 204, etc.

These estimates serve as the basis for understanding the behavior of gas flow and/or pressure within each segment and, by extension, the entire flow structure. Computed solutions may be used in subsequent operations for coupling equations between segments and for calibrating and validating the model against experimental data. The coupled equations can be referred to as the process model. In embodiments, the process model functions as a virtual sensor for pressure and/or other flow properties at one or more locations in a flow structure (e.g., one or more regions in a process chamber and/or at a surface of a substrate).

In an example, in the specific example provided, a process model derived from example flow structure 270 may deliver pressure and flow rate values at each boundary point 271A-D based on derived flow functions, conductance, and initial boundary conditions as extracted from sensor 272 (e.g., flow data 220).

In embodiments, the process model 260 may be derived via process 200, and then validated and adjust via experimental values. For example, in embodiments, imperfections within the equations within process model 260 may be characterized and modified by tracking experimental values within the real-world structure. The process model 260 may then be adjusted based on the differences between the real-world flow values, and the estimates produced by the process model.

In such a way, and in embodiments, process model 260 may be based on analytical flow equations produced via process 200, but be updated, and adjusted based on real-world, experimental flow values. For example, nuances, imperfections, or idiosyncrasies within a flow path and segments (e.g., changes in flow passage textures, physical imperfections, geometric imperfections, etc.) may slightly alter characteristics of the fluid flow within such a flow path. In embodiments, experimental values captured via sensors in the real-world flow path may capture the changes introduced via such imperfections.

In embodiments, system sensors may be placed along or within a portion of a flow path (or in any configuration with respect to a flow path) so as to provide data associated with fluid flow. In embodiments, a system sensor may capture data associated with any chamber or segment or pathway (e.g., a processing chamber, or any of path segments 204, etc.) of the system to gather experimental flow data. In embodiments, flow data that may be captured may be pressure data, flow rate data, indications of laminar or turbulent flow, etc., or any other kind of data that may be extractable, useful, and/or associated with fluid flow within a flow path.

Data from such experimental values may be used to update and adjust the process model 260 (and/or associated functions and parameters) to more accurately generate estimates. Through such updating and real-world comparison, process model 260 may incorporate enhanced versatility and accuracy for a given real-world flow path.

As such, in embodiments, process model 260 may serve as a foundational model in a further process of arriving at a more refined and accurate model. Thus, in embodiments, process model 260 may be referred to as a foundational model, and further experimentation and refinement to it may produce an effective, or operational, model.

In some cases, the process model 260 can be validated and adjusted, before application to similar structures. For example, if a manufacturing system involves a host of similar structures, for which it is impractical to fine-tune a specific process model, the model may be validated and fine-tuned for a subset, or a portion, of the flow structures. In such a way vast amounts of flow data, for many flow structures, may be formed and predicted based on limited information (e.g., initial flow, pressure, and flow structure geometry), that is much more accessible.

Thus, in summary, conductance values, geometric flow functions, and/or flow characteristics can be estimated and applied together with analytical flow equations for simplified geometric segments. This approach allows one to quickly arrive at relatively accurate estimation of flow parameters, which are essential for the predictive capabilities of the model.

In a further extension of the process 200, the process itself can be applied across a host of varying flow structures. The complexity of each structure can range from simple pipes and channels, which provide rapid calculations, to more complex geometries like turbines, diffusers, and reactors, and so on and so forth, that may be numerically solved. In one embodiment, adaptability of the model lies in its foundational step of segmenting any given flow structure into simpler geometric shapes for which analytical equations are well-known.

In an example, a complex reactor chamber might be segmented into a combination of cylinders, cones, and rectangular prisms. Each of these segments may then be modeled using established flow equations specific to the segment's geometry. For example, Navier-Stokes equations may be used for cylindrical segments and/or specialized equations may be used for conical segments.

By following this methodology, the model can be adapted to virtually any flow structure, regardless of its complexity. The model can also be calibrated and validated using experimental data to improve its predictive accuracy.

In a further embodiment of the process and system, once the process model-driven process has been successfully applied to various flow structures and validated, a machine learning model can be introduced to “take over” the task of predicting flow parameters. Typically, the machine learning model would be trained using vast amounts of data that may be hard to acquire. However, in the current system, the machine learning model could be trained on real data that has been augmented with samples from the data generated by a validated analytical model. Thus, the machine learning model might effectively learn the relationships between the shape of the flow structure and the resulting flow parameters. Such a machine learning model could intake, and output, more accurate, and precise data. In one embodiment, the machine learning model may be or include one or more neural networks such as convolutional neural networks (CNNs).

In an example, while the flow structure and a developed process model could incorporate further sensors for further flow data, or further resolution in structural data, such data may not be beneficial to an analytical model. This may be due to an analytical methodology that may be approximating, or averaging over portions of the flow structure.

In contrast, a learning algorithm could leverage finer and finer levels of data, even from sensors and locations that might not be relevant to the analytical model. Furthermore, a machine learning model would have the advantage of a time-view (e.g., may keep a moving window of reference). For example, a machine learning model may be a recurrent neural network (RNN). This would help in intaking far more variables, down to the impact of certain components, and even external pressures and ambient conditions.

In some embodiments, a neural network or a gradient boosting machine might be employed for this purpose. The input features for the machine learning model might include further resolution than the analytical model, such as geometric parameters of the segmented flow structure, such as dimensions, angles, and surface areas, as well as initial conditions such as inlet velocity, pressure, and/or temperature. The target variables would be the flow parameters and/or pressure parameters that the analytical model aims to predict, such as outlet velocity, pressure distribution, and temperature gradients.

After sufficient training, the machine learning model would be capable of predicting flow parameters and/or pressure parameters for new, unseen flow structures, provided they can be segmented into the geometric shapes the model has been trained on. The advantage of using a machine learning model is that it can make these predictions much more quickly than solving the analytical equations, making it suitable for real-time applications or scenarios where rapid decision-making is advantageous.

Moreover, the machine learning model may continue to improve its predictions over time by incorporating new data, either from further simulations using the analytical model or from actual experimental measurements.

Thus, in some embodiments, outputs of the analytical model may be used as leverage to generate more capable, accurate, and comprehensive trained machine learning models. This creates a dynamic, self-improving system that combines the rigor of analytical equations with the speed and adaptability of machine learning, offering a comprehensive solution for predicting gas flow parameters in a wide array of flow structures.

Regardless of the embodiment, both machine learning and application of analytical models will offer vast improvements, particularly in executing speed, over application of computational flow dynamics. Either embodiment will provide near-immediate solutions, allowing for near-immediate updating or understating a manufacturing process. This proves particularly advantageous when compared to rigorously solving the multiple partial differential equations, and involving the extensive computing capabilities for such.

With regards to training a machine learning model to estimate flow parameters and/or pressure parameters based on a single pressure measurement or a limited number of pressure measurements (e.g., a pressure measurement at or near a vacuum pump), the machine learning model may be trained using data sets comprising flow structure segments, input pressure values and/or flow values at one end of the flow structure segments and output pressure values and/or flow values at an opposite end of the flow structure segments. For each type of flow structure segment, the machine learning model may receive geometrical information about the flow structure segment (e.g., shape, length, diameter, etc.) and an input pressure and/or flow parameter, and may estimate a pressure and/or flow parameter at an opposite end of the flow structure segment. The estimated pressure and/or flow parameter may be compared to a known or calculated pressure and/or flow parameter at the opposite end, and a determined difference between the estimated value(s) and the calculated or known value(s) may be used to update the machine learning model. Additional training data may include combinations of segments and associated information. Ultimately, the machine learning model may be trained to receive as an input an arbitrary set of flow segments and their arrangement relative to one another and a pressure reading at one location within a flow structure, and to determine pressures and/or flow values at one or more other locations within the flow structure.

One type of machine learning model that may be used to perform some or all of the above asks is an artificial neural network, such as a deep neural network. Artificial neural networks generally include a feature representation component with a classifier or regression layers that map features to a desired output space. A convolutional neural network (CNN), for example, hosts multiple layers of convolutional filters. Pooling is performed, and non-linearities may be addressed, at lower layers, on top of which a multi-layer perceptron is commonly appended, mapping top layer features extracted by the convolutional layers to decisions (e.g. classification outputs). Deep learning is a class of machine learning algorithms that use a cascade of multiple layers of nonlinear processing units for feature extraction and transformation. Each successive layer uses the output from the previous layer as input. Deep neural networks may learn in a supervised (e.g., classification) and/or unsupervised (e.g., pattern analysis) manner. Deep neural networks include a hierarchy of layers, where the different layers learn different levels of representations that correspond to different levels of abstraction. In deep learning, each level learns to transform its input data into a slightly more abstract and composite representation. Notably, a deep learning process can learn which features to optimally place in which level on its own. The “deep” in “deep learning” refers to the number of layers through which the data is transformed. More precisely, deep learning systems have a substantial credit assignment path (CAP) depth. The CAP is the chain of transformations from input to output. CAPs describe potentially causal connections between input and output. For a feedforward neural network, the depth of the CAPs may be that of the network and may be the number of hidden layers plus one. For recurrent neural networks, in which a signal may propagate through a layer more than once, the CAP depth is potentially unlimited.

In one embodiment, one or more machine learning model is a recurrent neural network (RNN). An RNN is a type of neural network that includes a memory to enable the neural network to capture temporal dependencies. An RNN is able to learn input-output mappings that depend on both a current input and past inputs. The RNN will address past and future scans and make predictions based on this continuous scanning information. RNNs may be trained using a training dataset to generate a fixed number of outputs (e.g., to classify time varying data such as video data as belonging to a fixed number of classes). One type of RNN that may be used is a long short term memory (LSTM) neural network.

Training of a neural network may be achieved in a supervised learning manner, which involves feeding a training dataset consisting of labeled inputs through the network, observing its outputs, defining an error (by measuring the difference between the outputs and the label values), and using techniques such as deep gradient descent and backpropagation to tune the weights of the network across all its layers and nodes such that the error is minimized. In many applications, repeating this process across the many labeled inputs in the training dataset yields a network that can produce correct output when presented with inputs that are different than the ones present in the training dataset. In high-dimensional settings, such as large images, this generalization is achieved when a sufficiently large and diverse training dataset is made available.

For the model training, a training dataset containing hundreds, thousands, tens of thousands, hundreds of thousands or more data points may be used to form a training dataset. This data may be processed to generate one or multiple training datasets for training of one or more machine learning models. The machine learning models may be trained, for example, to estimate pressure values and/or flow values at one or more locations in a flow structure given an input pressure and/or other flow value at a point in the flow structure and information about the flow structure.

In one embodiment, generating one or more training datasets includes gathering information on one or more flow segments and associated equations and/or measured pressure and/or flow values at various locations in the flow segments. Labels for a training data item may include pressure values and/or flow values at one or more locations of one or more flow structure segments.

To effectuate training, processing logic inputs the training dataset(s) into one or more untrained machine learning models. Prior to inputting a first input into a machine learning model, the machine learning model may be initialized. Processing logic trains the untrained machine learning model(s) based on the training dataset(s) to generate one or more trained machine learning models that perform various operations as set forth above.

Training may be performed by inputting one or more of the input data into the machine learning model one at a time. Each input may include data from one or more flow structure segments and an input pressure value and/or flow value at a location of one or more of the flow structure segment(s).

The machine learning model processes the input to generate an output. An artificial neural network includes an input layer that consists of values in a data point (e.g., intensity values and/or height values of pixels in a height map). The next layer is called a hidden layer, and nodes at the hidden layer each receive one or more of the input values. Each node contains parameters (e.g., weights) to apply to the input values. Each node therefore essentially inputs the input values into a multivariate function (e.g., a non-linear mathematical transformation) to produce an output value. A next layer may be another hidden layer or an output layer. In either case, the nodes at the next layer receive the output values from the nodes at the previous layer, and each node applies weights to those values and then generates its own output value. This may be performed at each layer. A final layer is the output layer, where there is one node for each class, prediction and/or output that the machine learning model can produce. For example, for an artificial neural network being trained to estimate pressure values and/or flow values at one or more locations in a flow structure giving an input pressure value and/or flow value and information on one or more flow structure segments of the flow structure.

Processing logic may then compare the estimated flow values(s) and/or pressure value(s) to known or calculated pressure value(s) and/or flow value(s). Processing logic determines an error (i.e., a classification error) based on the differences between the output and the provided label(s). Processing logic adjusts weights of one or more nodes in the machine learning model based on the error. An error term or delta may be determined for each node in the artificial neural network. Based on this error, the artificial neural network adjusts one or more of its parameters for one or more of its nodes (the weights for one or more inputs of a node). Parameters may be updated in a back propagation manner, such that nodes at a highest layer are updated first, followed by nodes at a next layer, and so on. An artificial neural network contains multiple layers of “neurons”, where each layer receives as input values from neurons at a previous layer. The parameters for each neuron include weights associated with the values that are received from each of the neurons at a previous layer. Accordingly, adjusting the parameters may include adjusting the weights assigned to each of the inputs for one or more neurons at one or more layers in the artificial neural network.

Once the model parameters have been optimized, model validation may be performed to determine whether the model has improved and to determine a current accuracy of the deep learning model. After one or more rounds of training, processing logic may determine whether a stopping criterion has been met. A stopping criterion may be a target level of accuracy, a target number of processed images from the training dataset, a target amount of change to parameters over one or more previous data points, a combination thereof and/or other criteria. In one embodiment, the stopping criteria is met when at least a minimum number of data points have been processed and at least a threshold accuracy is achieved. The threshold accuracy may be, for example, 70%, 80% or 90% accuracy. In one embodiment, the stopping criteria is met if accuracy of the machine learning model has stopped improving. If the stopping criterion has not been met, further training is performed. If the stopping criterion has been met, training may be complete. Once the machine learning model is trained, a reserved portion of the training dataset may be used to test the model.

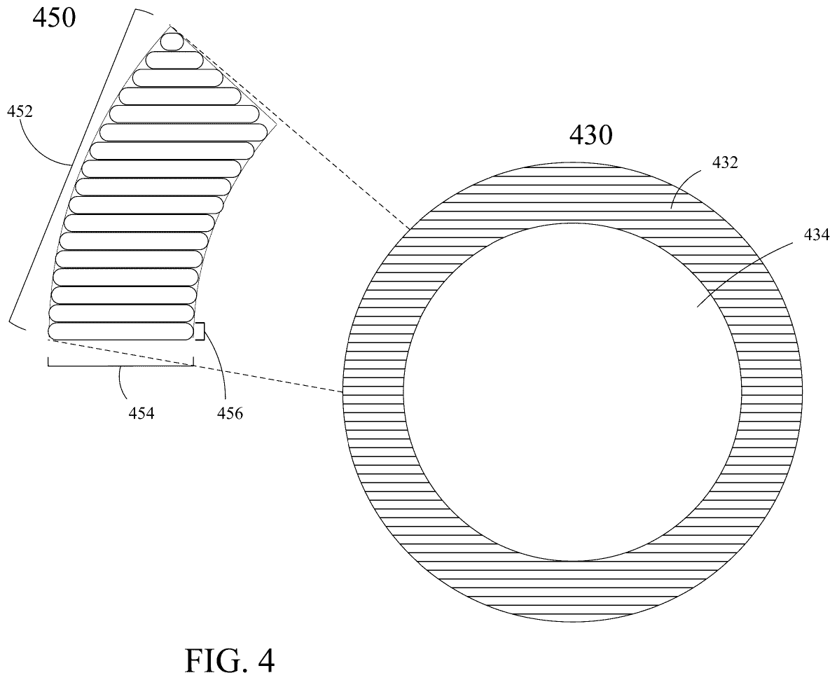

FIG. 3A illustrates an example flow structure 300A of a manufacturing system, according to some embodiments of the present disclosure. The previously described method of FIG. 2A may be applied to flow structure 300A. Reference will now be made with further specificities to the conductance values and flow structure geometries, with structure 300A in mind. Similarly, FIGS. 3B-C, and FIGS. 4-6 may reference the structure of FIG. 3A This is not meant to limit the disclosure with respect to those figures, and should be interpreted as an example combination, or one of many possible combinatory embodiments. In some embodiments, chamber 315 of FIG. 3A may correspond to, be similar to, or be an embodiment of chamber 178 of FIG. 1B, and incorporate and augment at least the embodiments described therein.

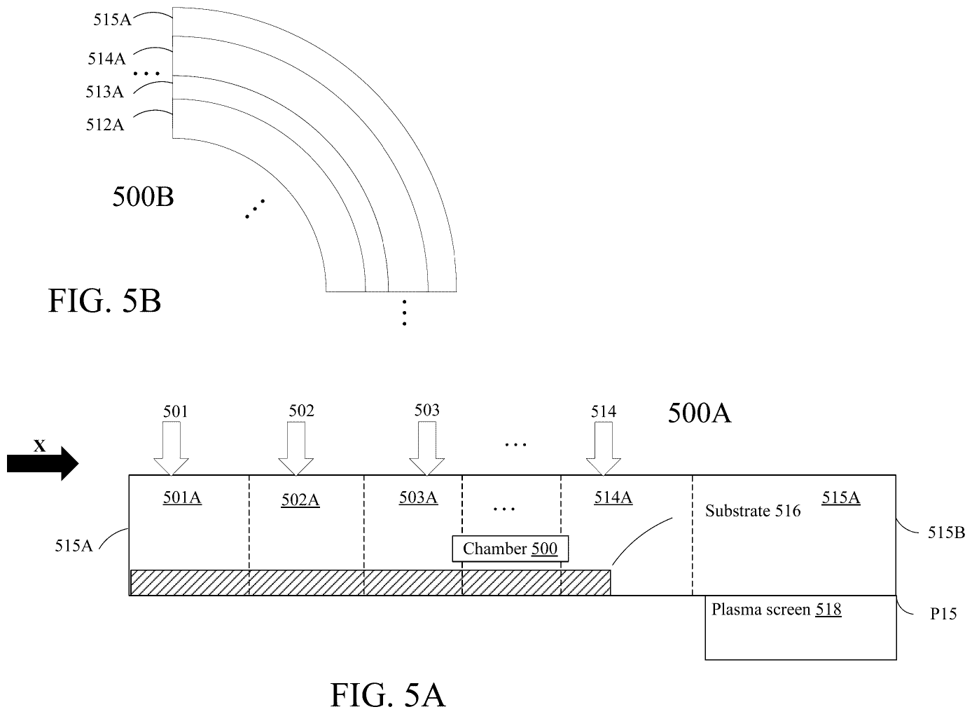

In some embodiments, flow structure 300A may include a processing chamber 315 and a substrate 316. Processing chamber may introduce gas through flow inlets 301-314. Inlets 301-314 may be, or include, one or more apertures (e.g., of a GDP), or nozzles, etc. for introducing gas into the chamber. Each inlet may introduce gas with a specific flow Qᵢ for i∈[1,14], such that Σᵢ₌₁¹⁴Qᵢ=Q_{T}. Q_{T} may quantify the total flow into the process chamber. Further details with respect to pressure within chamber 315 will be provided below with respect to FIGS. 5A-B. Gas may be introduced to the flow structure through inlets of chamber 315.

From chamber 315, a series of chambers, ports, and a plasma screen may lead to a vacuum source that is reducing, or “pumping down” the pressure P6 within the chamber 315. The ports and passageways leading from chamber 315 may be referred to as an exit flow path. Thus, gas flow may be referenced in the direction as moving from the chamber 315 to port 334, and onto a system vacuum source. In some embodiments, Q_{T}, which may quantify flow rate, may be a vector with a directional component. In other embodiments, Q_{T} may be a value defining flow rate.

With respect to the application of process 250, as described with respect to FIG. 2A, the flow structure has already undergone segmenting and standardization, as will be further described with respect to FIGS. 3B-C and 4-6. As can be seen in FIG. 3A, the flow structure includes segments of chamber 315, plasma screen 318, port 322, port 324, and ports 328 and 334. Computation of conductance values, flow functions, and process models, as were previously described with respect to FIG. 2A, will now be made with respect to these segments of FIG. 3A, throughout FIGS. 3B-C and 4-6. As mentioned above, this is not meant to be limiting, as in separate embodiments structures of 300A and or FIGS. 3B-6 and application of the model-driven prediction process may vary.

In some embodiments, process 250 as applied to structure 300A may begin with computing conductance values for each segment. In some embodiments, this may begin with port 334, which may include a sensor 336. Port 334 may be adjacent, or the segment most proximal a system vacuum source, and provide the most accurate pressure reading when the structure is in the vacuum state.

To determine a conductance value C₁ for port 334, port 334 may be standardized, or modeled as a rectangular duct, or a cube. The standardized equation for such a flow structure may be

$${C}_{1} = 3.54 \times 1 {0}^{- 2} Y ( \frac{{A}^{2}}{μ L} ) \overline{P} .$$

In the previous equation, 3.54×10⁻² is an equation constant. A is the cross-sectional rectangular area of the duct in cm², and μ represents the viscosity of the fluid within the duct in poise (generally a “look-up” value, constant for the type of fluid across an acceptable range of temperature and pressure). L is the length of the duct, in cm. P̅ is the average pressure at the boundary face P1 in dyne/cm². Finally, Y is the ratio of a width of the rectangle “a”, to a height of the rectangle “b”. This ratio may be represented as a value between 0 and 1. In the fringe case of a perfect square this value may be 1.

In some embodiments, the pressure P1 at the boundary face may be measured by one or more sensors of sensors 336. Thus, sensors 336 may include manometer pressure sensors, bourdon tube pressure sensors, diaphragm pressure sensors, capacitive pressure sensors, optical pressure sensors, thermal pressure sensors, or any other such or similar, or combination of such of similar pressure sensors that may be used within a manufacturing system.

FIG. 3B illustrates an exemplary rectangular duct segment 300B of port 334 of FIG. 3A, with the above values annotated, according to some embodiments of the present disclosure. Through the equation for C1, a conductance value for port 334 may be computed.

Continuing with conductance analysis, in some embodiments, port 328 may be adjacent to port 334. Port 328 may share a boundary condition with port 334. Port 328 may be an annular portion, or an inner cylinder within an outer cylinder, as seen by structure 300C in FIG. 3C.

FIG. 3C illustrates an exemplary annular flow segment of the flow structure of FIG. 3A, according to some embodiments of the present disclosure.

To determine a conductance value C2 for port 328, port 328 may be standardized or modeled as an annular region. The standardized equation for such a flow structure may be

$${C}_{2} = \frac{π}{8 μ} \frac{\overline{P}}{L} ( {R}_{O}^{4} - {R}_{I}^{4} - {( {R}_{O}^{2} - {R}_{I}^{2} )}^{2} / ln ( \frac{{R}_{0}}{{R}_{I}} ) ) .$$

In the previous equation, π is constant. μ represents the viscosity of the fluid within the duct in poise (generally a “look-up” value, constant for the type of fluid across an acceptable range of temperature and pressure). R_{O} is the outer radius of the annular region in cm. R_{I} is the inner radius of the annular region in cm. L is the length of the annular region, in cm. P̅ may be the average pressure at the boundary face P2 in dyne/cm². Finally, Y is the ratio of a width of the rectangle “a”, to a height of the rectangle “b”. This ratio may be as a value between 0 and 1.

Thus, a conductance value C2 for port 328 may be determined.

Continuing with conductance analysis, in some embodiments ports 324 and 322 may be adjacent to port 328. As described previously, similar boundary conditions may be shared between adjacent ports. In some embodiments, ports 324 and/or 322 may be rectangular ducts and/or annular regions (similar to ports 328 and 334), and conductance may be determined using similar techniques and values as were described with respect to port 328 and 334. In other embodiments, ports 322 and 324 may be any other geometric shape (cylindrical ducts, spherical chambers, rectangular chambers, etc.), for which conductance value calculations are known, can be performed, and/or can be derived.

Thus conductance values for ports 324 and 322 may be determined.

Continuing with conductance analysis, in some embodiments plasma screen 318 may be adjacent to port 322. Plasma screen 318 may share a boundary condition with port 322. Plasma screen 318 may similarly be modeled as an annular region (as was port 328), but may include several smaller passages, within the annular ring itself. A more detailed description of plasma screen 318 can be seen in FIG. 4.

FIG. 4, illustrates an exemplary plasma screen 430 of the structure 300A. Although the screen 430 can be presented as an annular figure with an inner block 434, the annular section 432 may be modeled via many passageways 452. This is seen in magnified portion 450.

In some embodiments, the passageways 452 may be of varying height 456 and width 454. In other embodiments, the dimensions for passageways 452 may be uniform, and may be position in a radially extending pattern (not shown in FIG. 4), around the area of the annular region.

To determine a conductance value C3 for plasma screen 318, the gas flow can be modeled as molecular flow through a large number N of rectangular slots. The case can be further simplified to one where a width of the rectangle is much larger than the height (e.g., a>>b). In the case of FIG. 4, where 454>>456. A standardized equation for N rectangular slots may then be applied. The standardized equation for such a flow structure may be C_{PS}=

$$9.71 {( \frac{T}{M} )}^{\frac{1}{2}} {ab}^{2} ( \frac{K}{L + 2.66 b} ) .$$

In the previous equation, 9.71 can be an equation constant. M can represents the molar mass of the gas within the screen in gm/g mol. T can be the temperature at the plasma screen in Kelvin. The variable “b” can be the height of the rectangle in cm. The variable “a” can be the width in cm. L can be the length of the annular region, in cm. Finally, P is the average pressure at the boundary face P5 in dyne/cm\hat{ }2. Finally, K can be a correction factor based on the ratio of a height of the rectangle “b”, to a width of the rectangle “a”. This ratio may generally be less than 1, as the height will generally be much smaller than the width.

Thus, a conductance value C_{PS} for plasma screen 318 may be determined.

After conductance values have been calculated, flow functions can be formed using the basic function that ΔP=Q_{T}/C. This function means that the pressure change across a segment is equal to the flow rate divided by the conductance of the segment. For example, if flow rate is very high and conductance is very low, the pressure will drop excessively across a segment. Alternatively, if conductance is very high, the segment can accommodate higher flow rates with less pressure drops.

Applying the following equation to our flow structure gives P₅:

$${P}_{5} = {P}_{1} + {Q}_{T} ( \frac{1}{C 1} + \frac{1}{C 2} + \frac{1}{C 3} + \frac{1}{C 4} + \frac{1}{CPS} ) .$$

In some embodiments, Q_{T} may also be measured at the outflow from port 334. In other embodiments, it may be measured at chamber 315, by summing each input flow from 301-314. Thus, a pressure value at the chamber junction, or interface, may be determined from a known pressure at the exit flow path, using the conductance values. Alternatively, the pressure at each interface (e.g., P1-P5) may also be calculated throughout the exit flow path.

In alternative embodiments where multiple gasses are used, the pressure may be predicted utilizing weighted averages for viscosity and molecular masses, weighted in accordance with the input flow rate for each gas.

In some embodiments, the passageways and components leading from chamber 315 to a vacuum source may be referred to as an exit flow path. Although FIG. 3A illustrates a specific configuration and sequence of ports, sensors, and a plasma screen, it is an example configuration. One of ordinary skill in the art, having the benefit of this disclosure, will appreciate that numerous layouts and configurations, components, and geometric structures for exit flow paths exist, and that the configuration as seen in FIG. 3A is an example representation associated with the system.

One of ordinary skill in the art, having the benefit of this disclosure, will also appreciate that multiple chambers and exit flow paths themselves may be combined. In other embodiments, multiple configurations and layouts for the larger structures may exist. One of ordinary skill in the art, having the benefit of this disclosure, will appreciate that the model produced by applying process 250 to such a flow structure can become much more complex and comprehensive to encompass such further configurations, layouts, and individual components. Further equations and computations for computing conductance scores according across a variety of structure may be included as is known in the art.

Turning now to chamber 315 and the pressure within, FIGS. 5A-B illustrate an example portion of a processing chamber as seen in FIG. 3A, according to some embodiments of the present disclosure.

As seen in side-view 500A of FIG. 5A, chamber 500, substrate 516, and plasma screen 518 may correspond, or be similar to chamber 315, substrate 316, and plasma screen 318 as seen and described in FIG. 3A, and incorporate and augment at least the embodiments described therein. In some embodiments, chamber 500 may have a height of 2 cm. In some embodiments, chamber 500 may have a height within the range of 0.5 cm to 15 cm.

As seen, chamber 500 can include varying pressure zones 501A-515A, corresponding to radial sections of the chamber. Zones 501A-515A can span a radial volume, or ring, of the chamber (e.g., into the page), as seen in partial top-down view 500B of FIG. 5B. As seen in partial top-down view 500B, each zone can have an outer radius, or extremity, and an inner radius, or extremity (not labeled in view 500B).

Returning to side-view 500A of FIG. 5A, pressure P15 at the radially outermost zone 515A (P15 is analogous to P5) may be calculated through the flow functions and conductance values as applied to FIGS. 3A-4. The pressure in each chamber may then be backtracked using the flow rate, and section number. The pressure can be backtracked using the equation

$${P}_{i} = {P}_{i + 1} + \frac{5808}{{h}^{3}} \times [ {\sum }_{i = 0}^{i} {Q}_{i} ] \times [ \frac{μ ln \frac{{OR}_{i}}{{IR}_{i}}}{{P}_{i + 1}} ] .$$

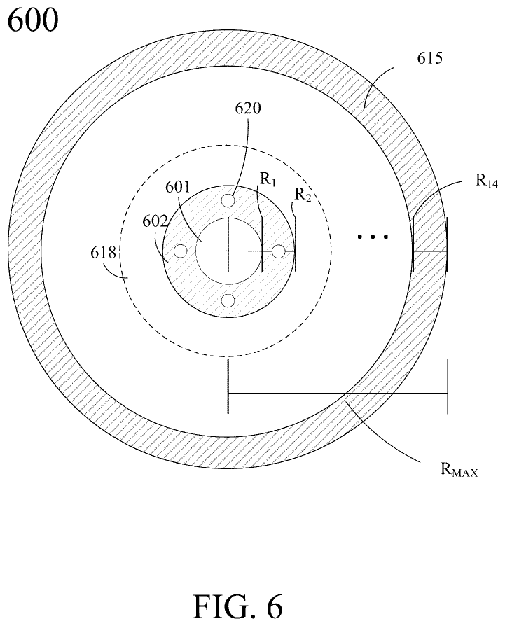

In the previous equation, i may be within i∈[1,14], such that each i corresponds to a zone 501A-514A, and each Pᵢ may correspond to a pressure within that zone. Qᵢ may correspond to the flow rate of each flow inlet, such that Q₁-Q₁₄ corresponds to the flow rates through flow inlets 501-514. μ, in poise, may represent the viscosity of the gas fluid being used, (generally a “look-up” value, constant for the type of fluid across an acceptable range of temperature and pressure). OR¿ may be the distance from a radial center of the chamber 500A to the outer radius of the zone i, and IRᵢ may be the distance from a radial center of the chamber 500A to the inner radius of the zone i. h, in cm, may be the chamber height. Thus, the pressure at different concentric zones within the processing chamber can be calculated. FIG. 6 will further illustrate embodiments of the processing chamber.

FIG. 6. illustrates a top-down view of example zones of a processing chamber of FIG. 3A, according to some embodiments of the present disclosure. In some embodiments, chamber 600 may correspond to, be similar to, or be an embodiment of the chamber 500, 315 and/or 178 of FIGS. 1A-B, 3 and 5A-B, and incorporate and augment at least the embodiments described therein.

As seen in FIG. 6, the chamber 600 may include radially concentric zones 601-615. Each concentric zone can be of an increasing, unique, outer radius. For example, as seen, zone 601 may include an outer radius R₁. Zone 602 may have an outer radius of R₂, and an inner radius or R_{I}, and so on and so forth for the remaining zones. Finally, zone 615 may have an inner radius of R₁₄ and an outer radius of R_{MAX}.

An example substrate can be included within the chamber as substrate 618. Substrate 618 may be of any radius as can be feasibly fit within the chamber of maximum radius R_{MAX. O} otherwise stated substrate 618 may be of any radius between 0 and R_{MAX}. In embodiments, the portion of the substrate within a zone may experience the estimated pressure level within such a zone.

As further seen within FIG. 6, each zone can include one or more gas flow inlets (e.g., as seen by inlets 620 in zone 602). Although inlets are shown with respect to zone 602, in embodiments it should be understood that each zone can include one or more flow inlets. Furthermore, in embodiments any arrangement of flow inlets can be arranged within a zone, to accommodate the number of flow inlets.

In embodiments, the flow rate, inlet diameter, radial position (as long as the inlet is still within the radial zone), number of inlets, and/or gas type at each flow inlet can vary.

For example, in embodiments each zone can include anywhere between 1-5 rows of flow inlets at varying radii (e.g., at radii ranging from the inner radius of the zone to the outer radius).

In embodiments, the diameter of the circular figure formed by the apertures or holes of flow inlets within any zone can be anywhere between 0.5 to 15 inches.

In embodiments, the number of flow inlets within one zone of zones 601-614 may be anywhere between 4 and 112.

In embodiments, zones can be combined into zone combinations, and flow rate can be established for each. For example, in embodiments, a zone flow Z1 may be set as the total combined flow from the inlets of zones 601-605. In embodiments, a zone flow Z2 may be set as the total combined flow from the inlets of zones 606-608. In embodiments, a zone flow Z3 may be set as the total combined flow from the inlets of zones 609-612. In embodiments, a zone flow Z4 may be set as the total combined flow from the inlets of zones 613-614.

In embodiments, the flow into each zone may be a fraction of the combined zone flow. For example, in embodiments, the flow through the inlets at zone 601 may be 4% of total combined flow Z1. In embodiments, the flow through the inlets at zone 602 may be 12% of total combined flow Z1. In embodiments, the flow through the inlets at zone 603 may be 20% of total combined flow Z1. In embodiments, the flow through the inlets at zone 604 may be 28% of total combined flow Z1. In embodiments, the flow through the inlets at zone 605 may be 36% of total combined flow Z1. In embodiments, the flow through the inlets at zone 606 may be 29% of total combined flow Z2. In embodiments, the flow through the inlets at zone 607 may be 33% of total combined flow Z2. In embodiments, the flow through the inlets at zone 608 may be 38% of total combined flow Z2. In embodiments, the flow through the inlets at zone 609 may be 21% of total combined flow Z3. In embodiments, the flow through the inlets at zone 610 may be 23% of total combined flow Z3. In embodiments, the flow through the inlets at zone 611 may be 25% of total combined flow Z3. In embodiments, the flow through the inlets at zone 612 may be 30% of total combined flow Z3. In embodiments, the flow through the inlets at zone 613 may be 48% of total combined flow Z4. In embodiments, the flow through the inlets at zone 614 may be 52% of total combined flow Z4.

In embodiments, the above percentages may be controlled through the number of flow inlets at each zone, the diameter of the flow inlets at each zone, etc. One of ordinary skill in the art, having the benefit of this disclosure, will appreciate that numerous strategies, layouts and configurations for controlling or dividing flow between each zone, and corresponding flow inlets within chamber 600 exist, and that the configuration and percentages described above with respect to chamber 600 are an exemplary representation of a chamber associated with the system.

Thus, the pressure within each zone of a processing chamber (e.g., a segment pressure map 222B as was described with respect to FIG. 2A), and the pressure at precise locations of a substrate within the processing chamber, can be estimated.

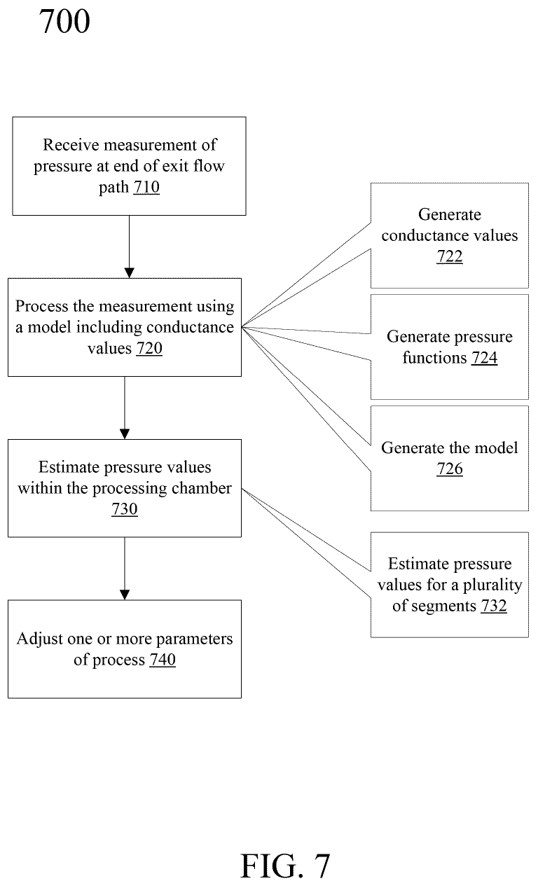

FIG. 7 illustrates a flow chart of an example method 700 for estimating pressure values within a processing chamber, according to some embodiments of the present disclosure.

Method 700 may be performed by processing logic that can include hardware (circuitry, dedicated logic, etc.), software (e.g., instructions run on a processing device), or a combination thereof. In one implementation, some, or all of the operations of method 700 can be performed by one or more components of system 100 of FIG. 1A.

At block 710, processing logic can receive measurements of pressure at and end of exit flow path. In some embodiments, processing logic can receive a measurement of a first pressure value at a terminal end of an exit flow path from a processing chamber.

At block 720, processing logic can process the measurement using a model including conductance values. In some embodiments, processing logic can process the measurement of the first pressure value using a model comprising conductance values for a plurality of segments of the exit flow path.

At block 722, processing logic can generate conductance values. In some embodiments, processing logic can generate conductance values for each given segment of the plurality of segments of the exit flow path based on a geometric structure of the given segment.

At block 724, processing logic can generate pressure functions. In some embodiments, processing logic can generate one or more pressure functions based on the conductance values.

At block 726, processing logic can generate the model. In some embodiments, processing logic can generate the model based on the one or more pressure functions.

At block 730, processing logic can estimate pressure values within the processing chamber. In some embodiments, processing logic can estimate one or more pressure values within the processing chamber.

At block 732, processing logic can estimate pressure values for a plurality of segments. In some embodiments, processing logic can use the pressure functions of the model to estimate the pressure value at each segment of the plurality of segments of the processing chamber

At block 740, processing logic may adjust one or more parameters of a process performed on a substrate. In some embodiments, processing logic can adjust one or more parameters of the process based on the one or more pressure values.

FIG. 8 illustrates an embodiment of a diagrammatic representation of a computing device associated with a substrate manufacturing system, in according to some embodiments of the present disclosure.

In one implementation, FIG. 8 illustrates a processing device 800 that may be a part of any computing device associated with any of the above-described figures, or any combination thereof. Example processing device 800 may be connected to other processing devices in a LAN, an intranet, an extranet, and/or the Internet. The processing device 800 may be a personal computer (PC), a set-top box (STB), a server, a network router, switch or bridge, or any device capable of executing a set of instructions (sequential or otherwise) that specify actions to be taken by that device. Further, while a single example processing device is illustrated, the term “processing device” shall also be taken to include any collection of processing devices (e.g., computers) that individually or jointly execute a set (or multiple sets) of instructions to perform any one or more of the methods discussed herein.

Example processing device 800 may include a processor 802 (e.g., a CPU), a main memory 804 (e.g., read-only memory (ROM), flash memory, dynamic random access memory (DRAM) such as synchronous DRAM (SDRAM), etc.), a static memory 806 (e.g., flash memory, static random access memory (SRAM), etc.), and a secondary memory (e.g., a data storage device 818), which may communicate with each other via a bus 830.

Processor 802 represents one or more general-purpose processing devices such as a microprocessor, central processing unit, or the like. More particularly, processor 802 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 802 may also be one or more special-purpose processing devices such as an application specific integrated circuit (ASIC), a field programmable gate array (FPGA), a digital signal processor (DSP), network processor, or the like. In accordance with one or more aspects of the present disclosure, processor 802 may be configured to execute instructions (e.g. instructions 822 may include a computing subsystem as seen at least in within the controllers and platforms of FIG. 1A). In embodiments, instructions 822 include instructions for a prediction engine 166 (e.g., which may function as a virtual sensor to detect pressure and/or flow at one or more regions in a process chamber that are not near a pressure or flow sensor).

Example processing device 800 may further comprise a network interface device 808, which may be communicatively coupled to a network 820. Example processing device 800 may further comprise a video display 810 (e.g., a liquid crystal display (LCD), a touch screen, or a cathode ray tube (CRT)), an alphanumeric input device 812 (e.g., a keyboard), an input control device 814 (e.g., a cursor control device, a touch-screen control device, a mouse), and a signal generation device 816 (e.g., an acoustic speaker).

Data storage device 818 may include a computer-readable storage medium (or, more specifically, a non-transitory computer-readable storage medium) 828 on which is stored one or more sets of executable instructions 822. In accordance with one or more aspects of the present disclosure, executable instructions 822 may comprise executable instructions.

Executable instructions 822 may also reside, completely or at least partially, within main memory 804 and/or within processor 802 during execution thereof by example processing device 800, main memory 804 and processor 802 also constituting computer-readable storage media. Executable instructions 822 may further be transmitted or received over a network via network interface device 808.

While the computer-readable storage medium 828 is shown in FIG. 8 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

It should be understood that the above description is intended to be illustrative, and not restrictive. Many other embodiment examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

The embodiments of methods, hardware, software, firmware or code set forth above may be implemented via instructions or code stored on a machine-accessible, machine readable, computer accessible, or computer readable medium which are executable by a processing element. “Memory” includes any mechanism that provides (i.e., stores and/or transmits) information in a form readable by a machine, such as a computer or electronic system. For example, “memory” includes random-access memory (RAM), such as static RAM (SRAM) or dynamic RAM (DRAM); ROM; magnetic or optical storage medium; flash memory devices; electrical storage devices; optical storage devices; acoustical storage devices, and any type of tangible machine-readable medium suitable for storing or transmitting electronic instructions or information in a form readable by a machine (e.g., a computer).

Reference throughout this specification to “one embodiment” or “an embodiment” means that a particular feature, structure, or characteristic described in connection with the embodiment is included in at least one embodiment of the disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the foregoing specification, a detailed description has been given with reference to specific exemplary embodiments. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of embodiment, embodiment, and/or other exemplarily language does not necessarily refer to the same embodiment or the same example, but may refer to different and distinct embodiments, as well as potentially the same embodiment.

The words “example” or “exemplary” are used herein to mean serving as an example, instance, or illustration. Any aspect or design described herein as “example′ or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such. Also, the terms “first,” “second,” “third,” “fourth,” etc. as used herein are meant as labels to distinguish among different elements and may not necessarily have an ordinal meaning according to their numerical designation.

A digital computer program, which may also be referred to or described as a program, software, a software application, a module, a software module, a script, or code, can be written in any form of programming language, including compiled or interpreted languages, or declarative or procedural languages, and it can be deployed in any form, including as a stand-alone program or as a module, component, subroutine, or other unit suitable for use in a digital computing environment. The essential elements of a digital computer a central processing unit for performing or executing instructions and one or more memory devices for storing instructions and digital data. The central processing unit and the memory can be supplemented by, or incorporated in, special purpose logic circuitry or quantum simulators. Generally, a digital computer will also include, or be operatively coupled to receive digital data from or transfer digital data to, or both, one or more mass storage devices for storing digital data, e.g., magnetic, magneto-optical disks, optical disks, or systems suitable for storing information. However, a digital computer need not have such devices.

Digital computer-readable media suitable for storing digital computer program instructions and digital data include all forms of non-volatile digital memory, media and memory devices, including by way of example semiconductor memory devices, e.g., EPROM, EEPROM, and flash memory devices; magnetic disks, e.g., internal hard disks or removable disks; magneto-optical disks; CD-ROM and DVD-ROM disks.

Control of the various systems described in this specification, or portions of them, can be implemented in a digital computer program product that includes instructions that are stored on one or more non-transitory machine-readable storage media, and that are executable on one or more digital processing devices. The systems described in this specification, or portions of them, can each be implemented as an apparatus, method, or system that may include one or more digital processing devices and memory to store executable instructions to perform the operations described in this specification.

While this specification contains many specific embodiment details, these should not be construed as limitations on the scope of what may be claimed, but rather as descriptions of features that may be specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily rely on the particular order shown, or sequential order, to achieve desirable results. In some cases, multitasking and parallel processing may be advantageous.

What is claimed is:

1. A method comprising:
receiving a measurement of a first pressure value at a terminal end of an exit flow path from a processing chamber; and
processing the measurement of the first pressure value using a model comprising conductance values for a plurality of segments of the exit flow path to estimate one or more pressure values within the processing chamber.

2. The method of claim 1, wherein the processing chamber is configured to perform a plasma-based process on a substrate comprising at least one of a deposition process, an etching process, an ashing process, or a cleaning process.

3. The method of claim 1, wherein the plurality of segments of the exit flow path comprises a segment that is at least one of a rectangular duct, a cylindrical duct, an annular duct, or a plasma screen.

4. The method of claim 1, wherein processing the measurement of the first pressure value using the model comprises:
generating conductance values for each given segment of the plurality of segments of the exit flow path based on a geometric structure of the given segment;
generating one or more pressure functions based on the conductance values; and
generating the model based on the one or more pressure functions.

5. The method of claim 4, further comprising:
adjusting a parameter of the one or more pressure functions of the model based on one or more experimental values associated with fluid flow within the exit flow path or the processing chamber.

6. The method of claim 1, wherein estimating the one or more pressure values within the processing chamber comprises estimating a second pressure value at a junction between the exit flow path and the processing chamber.

7. The method of claim 1, wherein the model comprises pressure functions for estimating pressure values for a plurality of segments of the processing chamber.

8. The method of claim 7, wherein estimating the one or more pressure values within the processing chamber based on the processed measurement comprises using the pressure functions of the model to estimate the pressure value at each segment of the plurality of segments of the processing chamber.

9. The method of claim 1, wherein the one or more pressure values within the processing chamber are estimated during a process performed on a substrate, and wherein the one or more pressure values comprise one or more pressure values at one or more regions of the substrate, the method further comprising:
adjusting one or more parameters of the process based on the one or more pressure values.

10. A system comprising:
a memory device; and
a processing device communicatively coupled to the memory device, wherein the processing device is to:
receive a measurement of a first pressure value at a terminal end of an exit flow path from a processing chamber; and
process the measurement of the first pressure value using a model comprising conductance values for a plurality of segments of the exit flow path to estimate one or more pressure values within the processing chamber.

11. The system of claim 10, wherein the processing chamber is configured to perform a plasma-based process on a substrate comprising at least one of a deposition process, an etching process, an ashing process, or a cleaning process.

12. The system of claim 10, wherein the plurality of segments of the exit flow path comprises a segment that is at least one of a rectangular duct, a cylindrical duct, an annular duct, or a plasma screen.

13. The system of claim 10, wherein processing the measurement of the first pressure value using the model comprises:
generating conductance values for each given segment of the plurality of segments of the exit flow path based on a geometric structure of the given segment;
generating one or more pressure functions based on the conductance values; and
generating the model based on the one or more pressure function.

14. The system of claim 10, wherein estimating the one or more pressure values within the processing chamber comprises estimating a second pressure value at a junction between the exit flow path and the processing chamber.

15. The system of claim 10, wherein the model comprises pressure functions for estimating pressure values for a plurality of segments of the processing chamber.

16. The system of claim 15, wherein estimating the one or more pressure values within the processing chamber based on the processed measurement comprises using the pressure functions of the model to estimate the pressure value at each segment of the plurality of segments of the processing chamber.

17. The system of claim 15, wherein the plurality of segments of the processing chamber are volumetric segments of the processing chamber, wherein each volumetric segment is arranged concentrically and comprises a unique pressure value.

18. The system of claim 10, wherein the one or more pressure values within the processing chamber are estimated during a process performed on a substrate, and wherein the one or more pressure values comprise one or more pressure values at one or more regions of the substrate, wherein the processing device is to further:
adjust one or more parameters of the process based on the one or more pressure values.

19. A non-transitory computer readable storage medium comprising instructions that, when executed by a processing device, causes the processing device to perform operations comprising:
receiving a measurement of a first pressure value at a terminal end of an exit flow path from a processing chamber; and
processing the measurement of the first pressure value using a model comprising conductance values for a plurality of segments of the exit flow path to estimate one or more pressure values within the processing chamber.

20. The non-transitory computer readable storage medium of claim 19, wherein processing the measurement of the first pressure value using the model comprises:
generating conductance values for each given segment of the plurality of segments of the exit flow path based on a geometric structure of the given segment;
generating one or more pressure functions based on the conductance values; and
generating the model based on the one or more pressure functions.
